(19) United States
(12) Patent Application Publication
(10) Pub. No.: US 2024/0351037 A1
(43) Pub. Date: Oct. 24, 2024

(54) TRANSISTOR OPTICAL TWEEZERS HAVING SYMMETRICAL LEAKAGE CURRENTS, AND MICROFLUIDIC DEVICE COMPRISING THE OPTICAL TWEEZERS

(71) Applicant: COLORTECH (SUZHOU) BIOTECHNOLOGY, Suzhou (CN)

(72) Inventors: Xiaohu Miao, Suzhou (CN); Peilian Li, Suzhou (CN); Peng Cheng, Suzhou (CN)

(21) Appl. No.: 18/757,643

(22) Filed: Jun. 28, 2024

Related U.S. Application Data
(63) Continuation of application No. PCT/CN2022/142196, filed on Dec. 27, 2022.

(30) Foreign Application Priority Data
Dec. 28, 2021 (CN) 202111625057.7

(51) Int. Cl. B01L 3/00

(52) U.S. Cl. CPC B01L 3/502761; B01L 3/50273; B01L 2200/0647

(57) ABSTRACT

The present invention provides an optical tweezers apparatus, including: a first electrode; a second electrode; a phototransistor array located between the first electrode and the second electrode, where the phototransistor array includes phototransistors distributed in an array, each phototransistor is physically isolated from each other by an insulating layer and an insulating barrier, and each phototransistor includes a collector region, a base region, and an emitter region on a substrate; and a microfluidic channel formed between the first electrode and the phototransistor array. The present invention further provides a microfluidic device including the optical tweezers apparatus.

### CROSS REFERENCE TO RELATED APPLICATIONS

The present application is a continuation application of International (PCT) Patent Application No. PCT/CN2022/142196, filed on Dec. 27, 2022, which claims priority of the Chinese patent application No. 202111625057.7, filed on Dec. 28, 2021, the entire contents of which are hereby incorporated by reference in their entireties.

### TECHNICAL FIELD

The present invention relates to a phototransistor-based optical tweezers apparatus, and specifically, to an optical tweezers apparatus capable of forming symmetrical leakage currents in an alternating current operating environment and a microfluidic device including the apparatus.

### BACKGROUND

A phototransistor-based optical tweezers technology is already applied to manipulate (for example, select or move) microobjects such as cells or microspheres. A typical structure of an optical tweezers apparatus of this type is as follows: A microfluidic channel is disposed between an upper electrode and a lower electrode, where the upper electrode is usually a glass plate coated with indium tin oxide (ITO), the lower electrode is a metal electrode, and a phototransistor array is disposed on the lower electrode to replace a common photoelectric layer. When patterned light is irradiated on a specific region of the phototransistor array, an activated phototransistor allows a current to pass through, thereby forming a non-uniform electric field in the microfluidic channel, and generating a dielectrophoresis (DEP) force that can manipulate the microobjects. A bias voltage applied between the two electrodes is usually an alternating current AC.

CN107223074B discloses phototransistor optical tweezers and a microfluidic apparatus thereof. Each phototransistor structure includes a lateral phototransistor and a vertical phototransistor. In each phototransistor structure, a P-type base region surrounds an N-type emitter region, an N-type collector region surrounds the P-type base region, and the base region and the collector region each include a lateral part and a vertical part. Compared with optical tweezers having only a vertical phototransistor, the phototransistor optical tweezers simultaneously generates a lateral current and a vertical current at a same light intensity, and it is claimed that the additional lateral phototransistor increases an intensity of the generated current, thereby allowing more stable control of microobjects.

CN107250344A discloses self-locking optical tweezers, where a DEP force generated by an annular lateral phototransistor is used to lock a single particle or cell in a dark state. The locked particle or cell may be selectively released by optically deactivating these locked sites. P-type silicon is used as a substrate for a phototransistor in the optical tweezers, an electrode with an annular pattern is formed through photolithography, and N-type ions are implanted between a large electrode and an island electrode to generate an NPN-type phototransistor. In this structure, the P-type silicon substrate constitutes the majority of the phototransistor.

Cells or particles contained in physiological liquid, a culture medium, and the like are injected from an inlet of a microfluidic channel, flow through the microfluidic channel, and leave from an outlet of the microfluidic channel. A physiological liquid or culture fluid environment in which the cells or particles are located contains a large amount of electrolytes, for example, various amino acids and inorganic ions (such as Ca²⁺, Na⁺, Cl⁻, K⁺, Mg²⁺, and PO₄³⁻), and therefore has a high conductivity, for example, 1 mS/cm to 10 mS/cm or higher. In the phototransistor optical tweezers, the base region of the phototransistor receives light irradiation to generate a current, and the current is amplified by the phototransistor to conduct the upper and lower electrodes. When an alternating current is applied between the two electrodes, a phototransistor that is not irradiated is in a cut-off state, but still generates a leakage current. Because a voltage of the alternating current periodically changes between positive and negative, the leakage current also changes between positive and negative. The inventors found that in a phototransistor structure provided in the conventional technology, a positive leakage current and a negative leakage current are not symmetrical, which is manifested as a significant difference between intensities of the positive leakage current and the negative leakage current when absolute values of voltages are equal. For example, when absolute values of a positive voltage and a negative voltage are equal, the intensity of the positive leakage current is obviously higher than the intensity of the negative leakage current. Therefore, there is always a potential difference applied to a high-conductivity sample in the microfluidic channel in any time period. Therefore, organisms and conductive substances in the sample are always subjected to voltage stress, which causes potential damage to the organisms such as cells and affects an experimental result, and intensifies an electrochemical reaction in a solution.

The array-type phototransistor optical tweezers disclosed in CN107223074B are used as an example, and a structure of the array-type phototransistor optical tweezers is shown in FIG. 5. Each phototransistor 526 is physically isolated from each other by an insulating layer 512 and an insulating barrier 520 extending to a support layer 510, and includes a base region 504, an emitter region 502, and a collector region 506. The support layer 510, the collector region 506, and the emitter region 502 may be doped with an N-type dopant, and the base region 504 may be doped with a P-type dopant. The support layer 510 and the emitter region 502 are heavily doped N+ regions with a resistivity of about 0.025 ohm·cm to 0.050 ohm·cm, and the collector region 506 is a lightly doped N region with a resistivity of about 5 ohm·cm to 10 ohm·cm. A ratio of the resistivity of the emitter region to the resistivity of the collector region is 1:100 to 1:400. A doping concentration of the N+ region may be about 10¹⁸ cm⁻³ to 10²¹ cm⁻³, and a doping concentration of the N region may be 10¹⁶ cm⁻³ to 10¹⁸ cm⁻³. As shown in the figure, a lateral width Wn of the collector region 506 is about 600 nm to about 750 nm, and a lateral width Wp of the base region 504 is about 200 nm to about 300 nm. A thickness He of the emitter region 502 is about 50 nm to about 150 nm. A thickness Hb of a vertical part of the base region 504 is 1 to 4 times Wp, that is, about 10 nm to about 1600 nm. A thickness Hc of a vertical part of the collector region 506 is 1 to 8 times Wn, that is, about 100 nm to about 8000 nm. The thickness Hc is about 4 to 7 times greater than the thickness Hb. The thickness Hc is about 11 to 17 times greater than the thickness He, that is, on both sides of the base region 504, the thickness of the emitter region 502 differs from that of the collector region 506 by a factor of 10 to 16.

FIG. 6A shows volt-ampere characteristic curves of a phototransistor based on the foregoing structure, where an alternating current AC is applied between two electrodes of an optical tweezers apparatus. When a patterned light is irradiated on the phototransistor, the phototransistor is turned on, and a volt-ampere characteristic curve of the phototransistor is shown as a curve A in the figure. In this case, a current intensity at a positive voltage is equivalent to a current intensity at a corresponding negative voltage. When there is no light irradiation, the phototransistor is in a cut-off state, but a leakage current still passes through the phototransistor, and a volt-ampere characteristic curve of the leakage current is shown as a curve B in the figure. A current intensity of the leakage current in a positive voltage cycle is obviously greater than a current intensity in a negative voltage cycle when absolute values of voltages are equal. For example, when +10 μV, an intensity of the leakage current is about +5 μA, which corresponds to an intercept S1 obtained on a vertical coordinate axis. When −10 μV, an intensity of the leakage current is about −2 μA, which corresponds to an intercept S2 obtained on a vertical coordinate axis. It can be clearly learned that S1 is significantly greater than S2. That is, at equal voltages in different directions, the leakage current is in different directions, and is significantly different in intensity. It can be learned that, in a specific period of time, there is always a potential difference on the microfluid, which induces or intensifies an electrochemical reaction.

An electrochemical reaction process is often accompanied by an electrode reaction of hydrogen or oxygen evolution on an electrode surface. Gases obtained through evolution are adsorbed on the electrode surface in a form of bubbles, resulting in a decrease in an electrode active area and non-uniform potential and current density microscopic distribution on the electrode surface, resulting in electrode polarization. When more bubbles are adsorbed on the electrode surface, a gas film is formed on the electrode surface, resulting in electrode passivation and inactivation. The gases obtained through evolution from the electrode surface are also dispersed in a solution in a form of bubbles, so that the solution becomes a gas-liquid mixed system, which affects generation of a non-uniform electric field and is not conducive to DEP force manipulation of microobjects such as cells.

In view of this, an improved optical tweezers apparatus and a corresponding microfluidic device are required in the art to overcome the foregoing defects in the conventional technology.

### SUMMARY

According to an aspect, the present invention provides an optical tweezers apparatus, including: a first electrode; a second electrode; a phototransistor array located between the first electrode and the second electrode, where the phototransistor array includes phototransistors distributed in an array, each phototransistor is physically isolated from each other by an insulating layer and an insulating barrier, each phototransistor includes a collector region, a base region, and an emitter region on a substrate, the collector region and the emitter region have a first doping type, and the base region has a second doping type; and a microfluidic channel formed between the first electrode and the phototransistor array. When an alternating current is applied between the first electrode and the second electrode, the phototransistor in a non-activated state has a positive leakage current and a negative leakage current respectively in a positive half cycle and a negative half cycle of the alternating current, and the collector region and the emitter region have substantially equal conductivities or resistivities, so that the phototransistor has substantially symmetrical positive leakage current and negative leakage current.

In some implementations, the emitter region includes a first doped region and a second doped region, and a doping concentration of the first doped region is greater than that of the second doped region. In some implementations, the doping concentration of the first doped region is about 10¹⁸ cm⁻³ to about 10²¹ cm⁻³. In some implementations, the doping concentration of the second doped region is about 10¹⁵ cm⁻³ to about 10¹⁸ cm⁻³.

In some implementations, the collector region and the second doped region have substantially equal doping concentrations. In some implementations, the doping concentrations of the collector region and the second doped region are about 10¹⁵ cm⁻³ to about 10¹⁸ cm⁻³.

In some implementations, the first doped region has a first thickness, the second doped region has a second thickness, and a ratio of the first thickness to the second thickness is about 1:1 to about 1:30, preferably about 1:5.

In some implementations, the collector region has a third thickness, the emitter region has a fourth thickness, and a ratio of the third thickness to the fourth thickness is about 1:5 to about 5:1, preferably, the ratio is about 1:1.

In some implementations, the collector region has a third thickness, and a ratio of the third thickness to the second thickness is about 1:5 to about 5:1, preferably, the ratio is about 1:1.

In some implementations, the base region, the first doped region, and the second doped region separately laterally extend to the insulating barrier.

In some implementations, the first doped region and the second doped region laterally extend, and the second doped region at least partially surrounds the first doped region. In some implementations, the second doped region surrounds the first doped region by a first lateral width of about 100 nm to about 2000 nm.

In some implementations, the base region, the first doped region, and the second doped region laterally extend, and the base region at least partially surrounds the first doped region and the second doped region. In some implementations, the base region surrounds the first doped region and the second doped region by a second lateral width of about 100 nm to about 2000 nm.

In some implementations, the base region, the first doped region, and the second doped region laterally extend, the base region at least partially surrounds the first doped region and the second doped region, and the second doped region at least partially surrounds the first doped region. In some implementations, the base region surrounds the first doped region and the second doped region by a second lateral width of about 100 nm to about 2000 nm, and the second doped region surrounds the first doped region by a first lateral width of about 100 nm to about 2000 nm.

In some implementations, the first thickness is about 100 nm to about 1000 nm. In some implementations, the second thickness is about 500 nm to about 3000 nm. In some implementations, a thickness of the base region is about 100 nm to about 5000 nm.

In some implementations, a ratio of the conductivity of the emitter region to the conductivity of the collector region is about 1:10 to about 10:1. In some implementations, the resistivity of the collector region is about 0.05 ohm·cm to about 10 ohm·cm. In some implementations, the resistivity of the emitter region is about 0.05 ohm·cm to about 10 ohm·cm.

In some implementations, the substrate and the first doped region have a same doping concentration. In some implementations, a resistivity of the substrate is about 0.001 ohm·cm to about 0.05 ohm·cm.

In some implementations, the first electrode is a glass plate coated with a conductive film. In some implementations, the conductive film is an indium tin oxide coating film. In some implementations, the second electrode is a metal electrode. In some implementations, the metal electrode is a gold electrode.

In some implementations, the first doping type is N-type doping, and the second doping type is P-type doping. In some implementations, the first doping type is P-type doping, and the second doping type is N-type doping.

In some implementations, a liquid sample is filled in the microfluidic channel, and a conductivity of the liquid sample is about 1 mS/cm to about 10 mS/cm. In some implementations, the liquid sample is a cell culture fluid or a physiological solution. In some implementations, the cell culture fluid or physiological solution includes cells. In some implementations, the cells are hybridoma cells.

In some implementations, the emitter region includes a plurality of emitter sub-regions.

According to another aspect, the present invention provides a microfluidic device, including a control system, an optical pattern generation system, an image collection system, and an optical tweezers apparatus, where the optical tweezers apparatus is any optical tweezers apparatus described in the present invention.

According to the optical tweezers apparatus and the microfluidic device provided in the present invention, when the alternating current is applied between the two electrodes of the optical tweezers apparatus, volt-ampere characteristic curves of the leakage currents on the non-activated phototransistor are symmetrical in the positive and negative cycles of the alternating current, thereby reducing or eliminating damage to cells or other microobjects in a microfluid and/or avoiding an electrochemical reaction. In some implementations, the symmetrical volt-ampere characteristic curves of the leakage currents are shown in FIG. 6B and FIG. 6C.

A person skilled in the art may aware that the volt-ampere characteristic curves of the leakage currents of the phototransistor may be affected by changing the doping concentrations and the thicknesses of the collector region and the emitter region on both sides of the base region. In the present invention, it is expected to maintain leakage current symmetry by maintaining substantially equal conductivities or resistivities (a reciprocal of the conductivity) of the collector region and the emitter region. Usually, an increase in the doping concentration causes an increase in the conductivity, thereby increasing the leakage current. An increase in the thickness causes an increase in the resistivity, thereby reducing the leakage current. For example, when the doping concentration and the thickness of the emitter region remain unchanged, increasing the doping concentration of the collector region and/or reducing the thickness of the collector region may increase the leakage current. Alternatively, when the doping concentration and the thickness of the collector region remain unchanged, increasing the doping concentration of the emitter region and/or reducing the thickness of the emitter region may increase the leakage current. Vice versa. In addition, the doping concentrations and thicknesses of the collector region and the emitter region may alternatively be simultaneously adjusted, to cooperatively adjust the conductivities (or the resistivities) of the collector region and the emitter region to maintain a symmetrical leakage current. When the emitter region includes a plurality of doped regions with different doping concentrations, a thickness and a doping concentration of one, more, or all of the doped regions may be changed individually or simultaneously to adjust the conductivity (or the resistivity) of the emitter region.

### BRIEF DESCRIPTION OF DRAWINGS

The present invention will be described in more detail with reference to the accompanying drawings. It should be noted that the illustrated solutions are merely representative examples of the implementations of the present invention, and for a clearer explanation of the details of the exemplary implementations, the elements in the accompanying drawings are not drawn in proportion to actual sizes, the quantity of actual elements may be changed, the relative positional relationship of the actual elements is basically the same as that illustrated in the figures, and some elements are not shown. When a plurality of embodiments exist, and when one or more features described in a previous embodiment may also be applied to another embodiment, for brevity, these repeatable applicable features should not be repeated in one or more subsequent embodiments, and the one or more subsequent embodiments should be understood to have described those repeatable applicable features, unless otherwise stated. A person skilled in the art will aware after reading the present invention that one or more features displayed in one diagram may be combined with one or more features in another diagram, to construct one or more alternative implementations not specifically shown in the accompanying drawings, and these alternative implementations also form a part of the present invention.

FIG. 1A is a partial sectional view of an optical tweezers apparatus according to an implementation of the present invention, FIG. 1B is a partial top view of a phototransistor array of the optical tweezers apparatus, FIG. 1C is a partial perspective view of the phototransistor array, and FIG. 1D is a schematic diagram of a microfluidic device including the optical tweezers apparatus;

FIG. 2A is a partial sectional view of a phototransistor array included in an optical tweezers apparatus according to another implementation of the present invention, and FIG. 2B is a partial top view of the phototransistor array;

FIG. 3A is a partial sectional view of a phototransistor array included in an optical tweezers apparatus according to still another implementation of the present invention, and FIG. 3B is a partial top view of the phototransistor array;

FIG. 4A is a partial sectional view of a phototransistor array included in an optical tweezers apparatus according to yet another implementation of the present invention, and FIG. 4B is a partial top view of the phototransistor array;

FIG. 5 is a partial sectional view of a phototransistor array included in an optical tweezers apparatus in the conventional technology;

FIG. 6A shows volt-ampere characteristic curves obtained based on the phototransistor in the conventional technology in FIG. 5, FIG. 6B shows volt-ampere characteristic curves obtained based on the phototransistor of the present invention in FIG. 1A and FIG. 2A, and FIG. 6C shows volt-ampere characteristic curves obtained based on the phototransistor of the present invention in FIG. 3A and FIG. 4A; and

FIG. 7 shows an exemplary manufacturing procedure of a phototransistor according to the present invention.

Meanings of reference numerals are summarized as follows. Reference numerals of a same number represent same elements. When applicable, repeated settings of a same element are represented by adding letters following a number. For example, reference numerals 108a, 108b, 108c, and 108d represent four repetitions of an element 108. 102 (102a, 102b), 202 (202a, 202b), 302 (302a,302b), 402 (402a,402b), 502-first doped region; 104, 204 (204a, 204b), 304, 404, 504-second doped region; 105, 205, 305, 405-emitter region; 106, 206, 306 (306a, 306b), 406, 506-base region; 108, 208, 308, 408, 508-collector region; 110, 210, 310, 410, 510-substrate; 112,112a, 112b-insulating layer; 114-conductive coating; 116-second electrode; 118, 118a, 118b, 118c,118d-cell; 120-insulating barrier; 122-microfluidic channel; 124-first electrode; 126,126a, 126b-phototransistor; 128-first electrode plate; 130-optical pattern generation apparatus; 132-image collection apparatus; 134-computer system; 136-microfluidic device; and 138-control system. H, W, and L represent sizes. N+, N−, and P represent doping types and doping levels.

### DESCRIPTION OF EMBODIMENTS

Exemplary implementations of the present invention are described in detail below with reference to the accompanying drawings. It should be understood that the scope of the present invention is not limited to the disclosed implementations. After reading the content disclosed in the present invention, a person skilled in the art may modify and change these exemplary implementations based on the enlightenment of the present invention without creative efforts, and the modifications and changes are intended to be included in the scope of the appended claims.

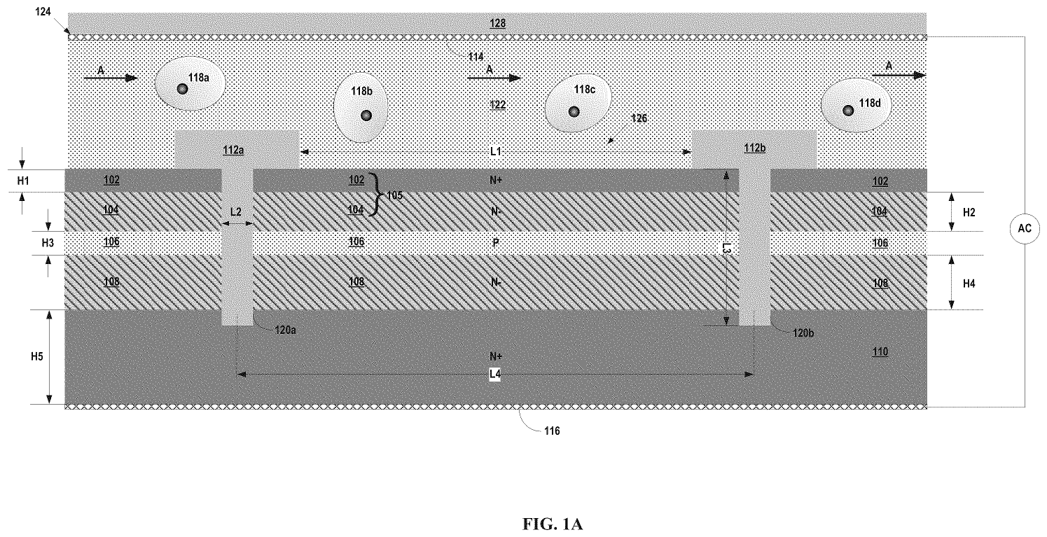

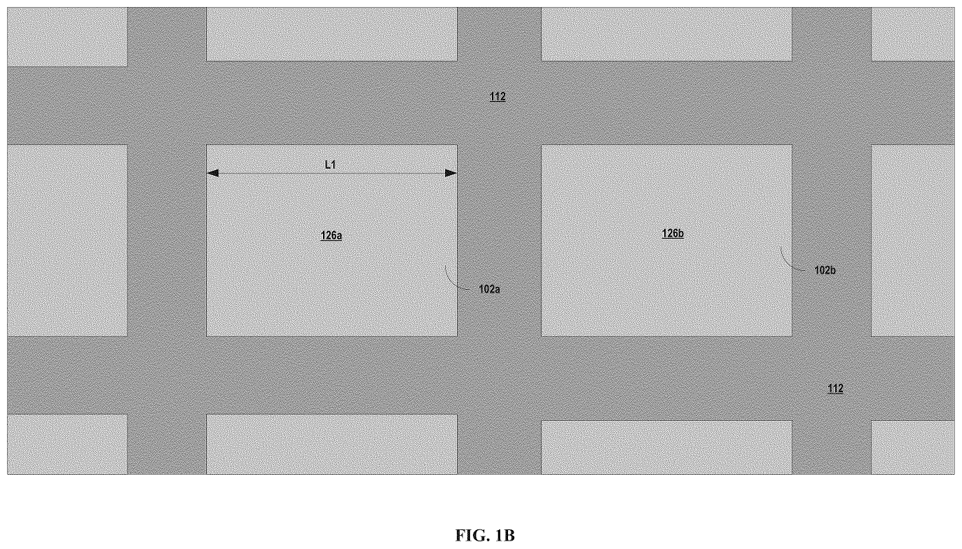

FIG. 1A is a schematic partial sectional view of an optical tweezers apparatus according to an implementation of the present invention. The optical tweezers apparatus includes a first electrode 124 formed by glass 128 coated with an indium tin oxide (ITO) conductive coating 114 and a second electrode 116 electrically connected to the first electrode 124, where an alternating current AC is applied between the two electrodes. A peak voltage of the alternating current AC is between about 1 Vppk and about 50 Vppk, and a frequency is between about 100 kHz and about 10 MHz. The alternating current AC may be a square waveform, a sine waveform, or a triangular waveform. The first electrode 124 may alternatively be another suitable ITO glass substitute known in the art, for example, AZO or GZO glass. The second electrode 116 is a metal electrode in this embodiment. Suitable metal electrodes include electrodes made of precious metals such as gold, silver, platinum, palladium, and iridium; metals such as copper, tin, antimony, iron, cobalt, nickel, chromium, titanium, and manganese; or alloys such as platinum-barium alloy, palladium-barium alloy, iridium-tungsten-rhenium alloy, and iridium-barium-osmium alloy. In this embodiment, the second electrode 116 is a gold electrode.

An array-type phototransistor structure is disposed on the second electrode 116, and is electrically connected to the second electrode 116. The array-type phototransistor structure includes a plurality of phototransistors 126 arranged in an array. An insulating assembly including an insulating layer 112 and an insulating barrier 120 (for example, SiO₂) physically isolates the phototransistors 126 from each other, to implement electrical insulation between the phototransistors 126. The figure shows three phototransistors 126 that are physically isolated from each other by two same insulating assemblies. The insulating layers 112a and 112b are located on a surface of the phototransistor 126, and the insulating barriers 120a and 120b extend downward respectively from the insulating layers 112a and 112b to s substrate layer 110 of the phototransistor 126. Each phototransistor 126 may be a phototransistor 126. The phototransistor 126 includes a substrate layer 110, a collector region 108 disposed on the substrate layer, a base region 106 disposed on the collector region 108, and an emitter region 105 disposed on the base region 106. An upper surface of the emitter region 105 forms an upper surface of the phototransistor 126, and a lower surface of the substrate layer 110 forms a lower surface of the phototransistor 126. The upper surface of the emitter region 105 is exposed to a microfluidic channel 122 and is opposite to the ITO conductive coating 114 of the first electrode 124, and the lower surface of the substrate layer 110 is electrically connected to the second electrode 116.

The array of the phototransistors 126 may be regular or irregular, but is preferably regular, for example, each phototransistor 126 is spaced from each other at an equal distance in a cubic or rectangular form. When the array of the phototransistors 126 is regularly arranged phototransistors 126, adjacent phototransistors 126 are spaced apart at a distance L4, and the distance is also referred to as a pixel period, and is a distance between vertical central axes of adjacent insulating barriers 120a and 120b. In this embodiment, L4 is about 5 microns to about 20 microns, for example, about 5 microns to about 15 microns, or about 5 microns to about 10 microns. A part that is of the phototransistor 126 and that is not covered by the insulating layer 112 is referred to as a window, and a size L1 of the window depends on the distance L4 and a size of a part that is of the phototransistor and that is covered by the insulating layer 112. Usually, the size L1 is about 20% to about 90% of the distance L4, for example, the size L1 is about 1 micron to about 18 microns, about 1 micron to about 12 microns, or about 1 micron to about 9 microns. A vertical depth L3 of the insulating barrier 120 is greater than a sum of a thickness (H1+H2) of the emitter region 105, a thickness H3 of the base region 106, and a thickness H4 of the collector region of the phototransistor 126, for example, about 10% to about 30% greater than the sum of the thicknesses. For example, L3 may be about 2 microns to about 10 microns, about 5 microns to about 10 microns, or about 8 microns to about 10 microns. A width L2 of the insulating barrier 120 may be about 100 nm to about 2000 nm, for example, about 500 nm to about 1500 nm, or about 800 nm to about 1000 nm. A person skilled in the art may aware that the sizes L1 to L4 are merely examples, and actual product sizes may be larger or smaller as required.

The emitter region 105 includes a first doped region 102 and a second doped region 104, where the second doped region 104 is adjacent to the base region 106, the first doped region 102 is disposed above the second doped region 104, and at least a part of the first doped region 102 directly faces the ITO conductive coating 114 of the first electrode 124. The insulating layer 112 at least partially covers the first doped region 102. The first doped region 102 and the second doped region 104 each laterally and parallelly extend to adjacent insulating barriers 120a and 120b. The first doped region 102 and the second doped region 104 have a same doping type, and the first doped region 102 has a doping concentration greater than that of the second doped region 104. For example, when both the first doped region 102 and the second doped region 104 include an N-type dopant, the first doped region 102 is a heavily doped region N+, and the second doped region 104 is a lightly doped region N−. When both the first doped region 102 and the second doped region 104 include a P-type dopant, the first doped region 102 is a heavily doped region P+, and the second doped region 104 is a lightly doped region P−. It should be noted that, unless otherwise stated, the terms “heavily doped region”, “lightly doped region”, and corresponding symbols thereof are used in the present invention only in relative senses thereof, that is, when a doping concentration of one doped region is greater than that of the other doped region, the region with a higher doping concentration is referred to as the heavily doped region, and the region with a lower doping concentration is referred to as the lightly doped region. The terms “heavily doped region”, “lightly doped region”, and corresponding symbols thereof are not necessarily related to absolute values of actual doping concentrations thereof. In another embodiment, the emitter region 105 may include a plurality of (for example, two or four) emitter sub-regions 105, and all the emitter sub-regions share the base region 106 and the collector region 108. Each emitter sub-region 105 is isolated by the base region 106, so that a light irradiation area of the base region 106 is increased, thereby facilitating generation a larger DEP force, and facilitating manipulation of microobjects in the microfluidic channel.

The doping concentration of the first doped region 102 may be about 10 times to about 10⁶ times the doping concentration of the second doped region 104. For example, the doping concentration of the first doped region 102 may be about 10² times to about 10⁵ times or about 10³ times the doping concentration of the second doped region 104. For example, the doping concentration of the first doped region 102 may be about 10¹⁸ cm⁻³ to about 10²¹ cm⁻³, and the doping concentration of the second doped region 104 may be about 10¹⁵ cm⁻³ to about 10¹⁸ cm⁻³. In this embodiment, the doping concentration of the first doped region 102 may be about 1×10¹⁸ cm⁻³, and the doping concentration of the second doped region 104 may be about 1×10¹⁶ cm⁻³. The N-type dopant may be any source of electrons. Examples of a suitable N or N+ dopant include phosphorus, arsenic, antimony, and the like. The P-type dopant may be any source of holes. Examples of a suitable P or P+ dopant include boron, aluminum, beryllium, zinc, cadmium, indium, and the like.

The base region 106 laterally extends to adjacent insulating barriers 120a and 120b. In the illustrated embodiment, the base region 106 includes a P-type dopant. A suitable doping concentration may be about 10¹⁶ cm⁻³ to about 10¹⁸ cm⁻³. In this embodiment, a doping concentration of the base region 106 is about 1×10¹⁶ cm⁻³. The base region 106 has a suitable thickness H3, which is, for example, about 100 nm to about 5000 nm, about 100 nm to about 2500 nm, about 100 nm to about 2000 nm, about 100 nm to about 1500 nm, about 100 nm to about 1000 nm, about 100 nm to about 500 nm, about 100 nm to about 300 nm, about 300 nm to about 3000 nm, about 300 nm to about 2500 nm, about 300 nm to about 2000 nm, about 300 nm to about 1500 nm, about 300 nm to about 1000 nm, about 300 nm to about 500 nm, about 500 nm to about 3000 nm, about 500 nm to about 2500 nm, about 500 nm to about 2000 nm, about 500 nm to about 1500 nm, about 500 nm to about 1000 nm, about 1000 nm to about 3000 nm, about 1000 nm to about 2500 nm, about 1000 nm to about 2000 nm, about 1000 nm to about 1500 nm, about 1500 nm to about 3000 nm, about 1500 nm to about 2500 nm, about 1500 nm to about 2000 nm, about 2000 nm to about 3000 nm, or about 2000 nm to about 2500 nm. In this embodiment, the thickness H3 of the base region 106 is about 500 nm. When a patterned light beam (see FIG. 1D) is irradiated on the phototransistor 126, the light beam passes through the emitter region 105 to reach the base region 106, thereby generating a photoelectric effect and turning on the phototransistor 126.

The collector region 108 and the emitter region 105 are symmetrically distributed with respect to the base region 106, and laterally extend to adjacent insulating barriers 120a and 120b. The second doped region 104 of the emitter region 105 and the collector region 108 may have a same doping type. For example, both the second doped region 104 and the collector region 108 include an N-type dopant. The doping concentration of the second doped region 104 may be substantially the same as that of the collector region 108. For example, the doping concentrations of the second doped region 104 and the collector region 108 are both about 10¹⁵ cm⁻³ to about 10¹⁸ cm⁻³. The term “doping concentrations are substantially the same” herein means that a doping concentration ratio of a compared object to a reference object is about 1:10 to about 10:1, for example, the doping concentration ratio is about 1:5 to about 5:1, about 1:3 to about 3:1, about 1:2 to about 2:1, about 1:1.5 to about 1.5:1, about 1:1.2 to about 1.2:1, or about 1:1.1 to about 1.1:1. In this embodiment, the doping concentration of the collector region 108 is 2×10¹⁵ cm⁻³.

The substrate layer 110 is located at a bottom of the phototransistor 126 and is directly electrically connected to the second electrode 116. The substrate layer 110 includes an N-type dopant in this embodiment. The substrate layer 110 may be a heavily doped region relative to the collector region 108. The substrate layer 110 and the first doped region 102 of the emitter region 105 may have substantially the same doping concentrations. For example, the doping concentration of the substrate layer 110 is about 10¹⁸ cm⁻³ to about 10²¹ cm⁻³. A thickness H5 of the substrate layer 110 may be a suitable thickness usually accepted in the art. For example, the thickness H5 of the substrate layer 110 is usually greater than 50 microns, for example, about 50 microns to about 500 microns, about 50 microns to about 450 microns, about 50 microns to about 400 microns, about 50 microns to about 350 microns, about 50 microns to about 300 microns, about 50 microns to about 250 microns, about 50 microns to about 200 microns, about 50 microns to about 150 microns, or about 50 microns to about 100 microns. In this embodiment, the thickness H5 of the substrate 110 is about 50 microns. The substrate layer 110 may have a resistivity of about 0.001 ohm·cm to about 0.05 ohm·cm.

In the emitter region 105, the thickness H1 of the first doped region 102 is preferably less than the thickness H2 of the second doped region 104. For example, the thickness H1 of the first doped region 102 is about 1/1 to about 1/30, about 1/5 to about 1/30, about 1/5 to about 1/20, about 1/5 to about 1/15, about 1/5 to about 1/10, about 1/10 to about 1/30, about 1/10 to about 1/20, about 1/10 to about 1/15, about 1/15 to about 1/30, about 1/15 to about 1/25, or about 1/15 to about 1/20 of the thickness H2 of the second doped region 104. Therefore, the second doped region 104 forms a main part of the emitter region 105. For example, the thickness H1 of the first doped region 102 is about 100 nm to about 1000 nm, for example, about 100 nm to about 800 nm, about 100 nm to about 500 nm, about 100 nm to about 300 nm, about 100 nm to about 200 nm, about 500 nm to about 1000 nm, about 500 nm to about 800 nm, or about 800 nm to about 1000 nm. The thickness H2 of the second doped region 104 may be about 500 nm to about 3000 nm, for example, about 500 nm to about 2500 nm, about 500 nm to about 2000 nm, about 500 nm to about 1500 nm, about 500 nm to about 1000 nm, about 1000 nm to about 3000 nm, about 1000 nm to about 2500 nm, about 1000 nm to about 2000 nm, about 1000 nm to about 1500 nm, about 1500 nm to about 3000 nm, about 1500 nm to about 2500 nm, or about 1500 nm to about 2000 nm. In this embodiment, the thickness H1 of the first doped region 102 is about 500 nm, and the thickness H2 of the second doped region 105 is about 2000 nm.

The emitter region 105 and the collector region 108 on both sides of the base region 106 may have substantially the same thicknesses, that is, a sum of the thickness H1 of the first doped region 102 and the thickness H2 of the second doped region 104 of the emitter region 105 is substantially the same as the thickness H4 of the collector region 108. The thickness H1 of the first doped region 102 may be increased or reduced in a range, and the thickness H2 of the second doped region 104 may be correspondingly reduced or increased, so that a total thickness H1+H2 of the first doped region 102 and the second doped region 104 is substantially the same as the thickness H4 of the collector region 108. For example, a ratio of the total thickness H1+H2 to the thickness H4 is about 1:5 to about 5:1, for example, about 1:4 to about 4:1, about 1:3 to about 3:1, about 1:2 to about 2:1, about 1:1.5 to about 1.5:1, about 1:1.2 to about 1.2:1, about 1:1.1 to about 1.1:1, or about 1:1. In an embodiment, the total thickness H1+H2 is greater than the thickness H4. In another embodiment, the total thickness H1+H2 is less than the thickness H4. In still another embodiment, the total thickness H1+H2 is equal to the thickness H4.

In some embodiments, only the thickness H2 of the second doped region 104 and the thickness H4 of the collector region 108 are substantially the same. For example, a ratio of the thickness H2 to the thickness H4 is about 1:5 to about 5:1, for example, about 1:4 to about 4:1, about 1:3 to about 3:1, about 1:2 to about 2:1, about 1:1.5 to about 1.5:1, about 1:1.2 to about 1.2:1, about 1:1.1 to about 1.1:1, or about 1:1. In an embodiment, the thickness H2 is greater than the thickness H4. In another embodiment, the thickness H2 is less than the thickness H4. In still another embodiment, the thickness H2 is equal to the thickness H4.

In some embodiments, the foregoing exemplary thicknesses and doping concentrations of the first doped region 102, the second doped region 104, and the collector region 108 may be changed (for example, simultaneously increased or reduced by a same magnitude), so that the conductivities of the emitter region 105 and the collector region 108 are always substantially the same. For example, the conductivities of the emitter region 105 and the collector region 108 may be simultaneously increased, for example, by reducing the thickness of the first doped region 102 and/or the second doped region 104 and the thickness of the collector region 108, or by increasing the doping concentration of the first doped region 102 and/or the second doped region 104 and the doping concentration of the collector region 108. Alternatively, the conductivities of the emitter region 105 and the collector region 108 may be simultaneously increased by reducing the thickness of the emitter region 105 and increasing the doping concentration of the collector region 108, or by increasing the doping concentration of the emitter region and reducing the thickness of the collector region 108. Optionally, the conductivities of the emitter region 105 and the collector region 108 are simultaneously reduced by increasing the thickness of the emitter region 105 and reducing the doping concentration of the collector region 108, or reducing the doping concentration of the emitter region 105 and increasing the thickness of the collector region 108.

It may be expected that the thickness and the doping concentration of the emitter region 105 may be simultaneously changed (for example, reduced or increased), and the thickness and the doping concentration of the collector region 108 may also be simultaneously changed, to obtain consistently increased or reduced conductivities. For example, the thickness of the emitter region 105 may be reduced (by reducing the thickness of at least one of the first doped region 102 or the second doped region 104) and the doping concentration of the emitter region 105 may be increased (by increasing the doping concentration of at least one of the first doped region 102 or the second doped region 104) to collectively increase the conductivities. Alternatively, the thickness of the emitter region 105 may be increased and the doping concentration of the emitter region 105 may be reduced, to collectively reduce the conductivities. The foregoing description of the emitter region 105 may also be applied to the collector region 108. Details are not described again for brevity.

It may be expected that, for a case in which the conductivity is increased by reducing the thickness and/or increasing the doping concentration or the conductivity is reduced by increasing the thickness and/or reducing the doping concentration, magnitudes for increasing or reducing the conductivities should be substantially the same in the emitter region 105 and the collector region 108, so that the conductivities of the emitter region 105 and the collector region 108 are always substantially equal. For example, a conductivity ratio of the emitter region 105 to the collector region 108 is about 1:10 to about 10:1, for example, about 1:8 to about 8:1, about 1:6 to about 6:1, about 1:5 to about 5:1, about 1:3 to about 3:1, about 1:2 to about 2:1, about 1:1.2 to about 1.2:1, about 1:1.1 to about 1.1:1, or about 1:1. In this embodiment, the conductivity of the emitter region 105 is about 12 S/cm, and the conductivity of the collector region 108 is about 2 S/cm.

In all of the embodiments described above, the thickness H4 may be about 100 nm to about 15000 nm, for example, about 500 nm to about 15000 nm, about 1000 nm to about 15000 nm, about 1000 nm to about 12000 nm, about 1000 nm to about 10000 nm, about 1000 nm to about 8000 nm, about 1000 nm to about 6000 nm, about 1000 nm to about 4000 nm, about 1000 nm to about 3000 nm, about 1000 nm to about 2000 nm, about 1000 nm to about 1500 nm, about 500 nm to about 1000 nm, about 500 nm to about 1500 nm, about 500 nm to about 2000 nm, about 500 nm to about 2500 nm, about 500 nm to about 3000 nm, about 500 nm to about 3500 nm, about 500 nm to about 4000 nm, about 500 nm to about 4500 nm, about 500 nm to about 5000 nm, about 500 nm to about 5500 nm, about 500 nm to about 6000 nm, about 500 nm to about 6500 nm, about 500 nm to about 7000 nm, about 500 nm to about 7500 nm, or about 500 nm to about 8000 nm. In this embodiment, the thickness H4 is about 5000 nm.

In this embodiment, the optical tweezers apparatus further includes a microfluidic channel 122 located between the upper surface of the phototransistor array and a lower surface of the conductive coating 114 of the first electrode 124. The microfluidic channel 122 usually includes a plurality of microchannels connected in series or in parallel, each microchannel includes a plurality of addressable micropores, and cells or other microobjects may be located in the micropores. The microfluidic channel 122 includes a fluid inlet and a fluid outlet (not shown) for fluid communication with the outside, a microfluid (for example, a cell culture fluid or a physiological solution) containing cells 118 (shown as cells 118a, 118b, 118c, and 118d, for example, antibody-secretable hybridoma cells) flows into the microfluidic channel 122 through the inlet, flows through the microfluidic channel 122 in a direction shown by an arrow A for processing and operations (including photoelectric detection, culture, screening, movement, and the like), and finally flows out from the outlet, thereby implementing an operation procedure of a microfluidic chip. The microfluidic channel 122 is usually made of a polymer material, for example, PMMA, PC, PS, PP, PE, or PDMS, or is prepared by using a photocuring agent. A height of the microfluidic channel 122 is usually at a micron level, for example, 20 microns to 50 microns.

FIG. 1B is a partial top view of a phototransistor array of the optical tweezers apparatus, FIG. 1C is a partial sectional view of an array-type phototransistor formed by the phototransistor 126 of the structure shown in FIG. 1A. FIG. 1D is a schematic diagram of a part of a microfluidic device 136 of an optical tweezers apparatus including the phototransistor 126 of the structure shown in FIG. 1A. The microfluidic device 136 includes an optical tweezers apparatus and a control system 138. The control system 138 usually includes a computer system 134, and an image collection apparatus 132 and an optical pattern generation apparatus 130 that are communicatively connected to the computer system 134. The image collection apparatus 132 is configured to collect an image of the microfluidic channel and/or the micropore, for example, is a camera with a CCD chip. The optical pattern generation apparatus 130 is configured to generate a patterned light beam to activate the phototransistor. An intensity of the light beam may be about 0.1 W/cm² to about 1000 W/cm². The computer system 134 is communicatively connected to the optical tweezers apparatus, and controls, according to a preset instruction, an interaction among the image collection apparatus 132, the optical pattern generation apparatus 130, and the optical tweezers apparatus, to complete a microfluidic operation.

FIG. 6B shows volt-ampere characteristic curves of the phototransistor according to this embodiment, where the alternating current AC is applied between the two electrodes of the optical tweezers apparatus. When the patterned light is irradiated on the phototransistor, the phototransistor is turned on, and a volt-ampere characteristic curve of the phototransistor is shown as a curve A in the figure. In this case, a current intensity at a specific positive voltage is equivalent to a current intensity at a corresponding negative voltage. When there is no light irradiation, the phototransistor is in a cut-off state, but a leakage current still passes through the phototransistor, and a volt-ampere characteristic curve of the leakage current is shown as a curve B in the figure. A current intensity of the leakage current in a positive voltage cycle is almost the same as (that is, “symmetrical with”) that at an equal voltage in a negative voltage cycle. For example, when +10 μV, an intensity of the leakage current is about +2.5 μA, which corresponds to an intercept S3 obtained from vertical coordinates. When −10 μV, an intensity of the leakage current is about −2.5 μA, which corresponds to an intercept S4 obtained from vertical coordinates. Compared with the conventional technology in FIG. 6A, an intensity of a positive leakage current is significantly reduced, the intensity of the positive leakage current is basically the same as that of a negative leakage current, and the volt-ampere characteristic curve is basically symmetric in a positive cycle and a negative cycle, thus significantly reducing or eliminating a possibility of an electrochemical reaction.

As described above, it is expected that the doping concentrations and the thicknesses of the collector region 108 and the emitter region 105 may be adjusted, provided that the volt-ampere characteristic curve of the leakage current of the phototransistor 126 shows that the positive and negative leakage currents have substantially equal change magnitudes, that is, in positive and negative voltage change cycles of the alternating current, when the phototransistor 126 is not activated through light irradiation, the volt-ampere characteristic curve of the leakage current is basically symmetrical in the positive cycle and the negative cycle. Therefore, a difference between the leakage currents flowing on the microobjects such as the microfluid and the cells 118 in the microfluid in the microfluidic channel corresponding to the phototransistor 126 is zero or substantially zero. The term “substantially zero” herein means that the difference between the leakage currents is small enough not to be considered to cause damage to the cells of the microfluid or other microobjects, or to induce or intensify the electrochemical reaction. For example, the difference may be about 1% to about 10%, about 1% to about 5%, or about 1% to about 3% of a peak leakage current, or more or less.

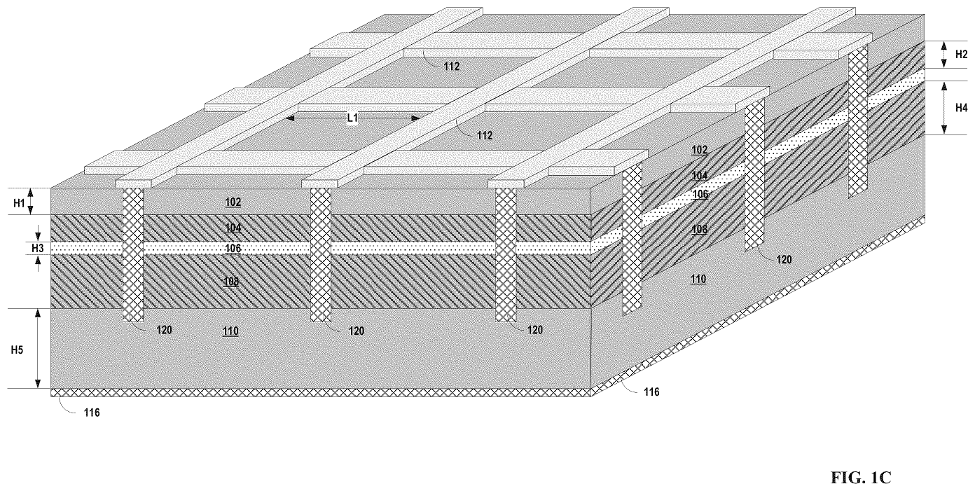

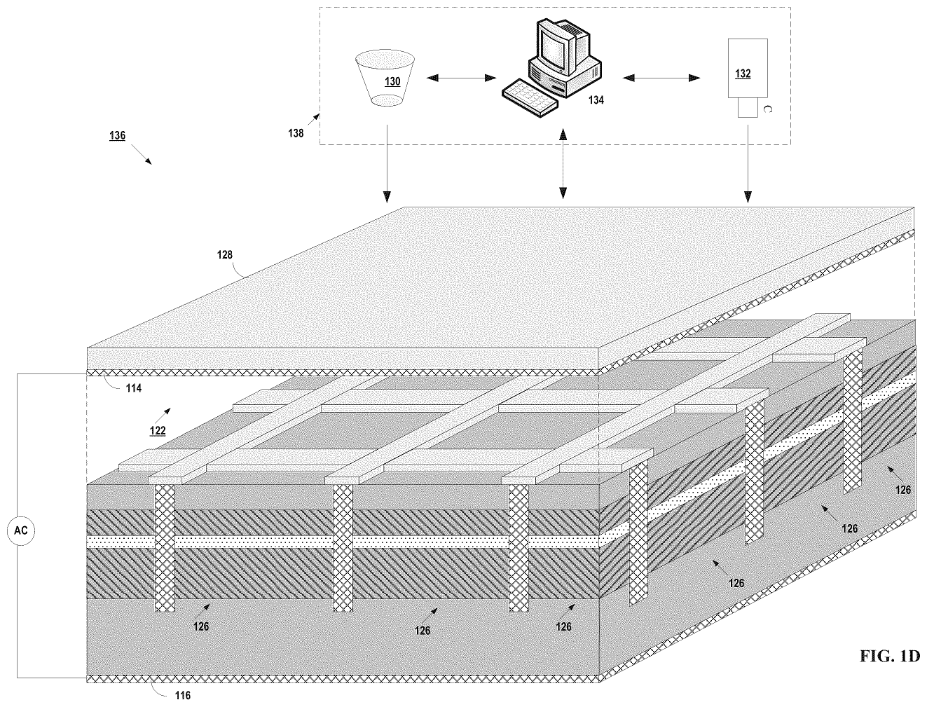

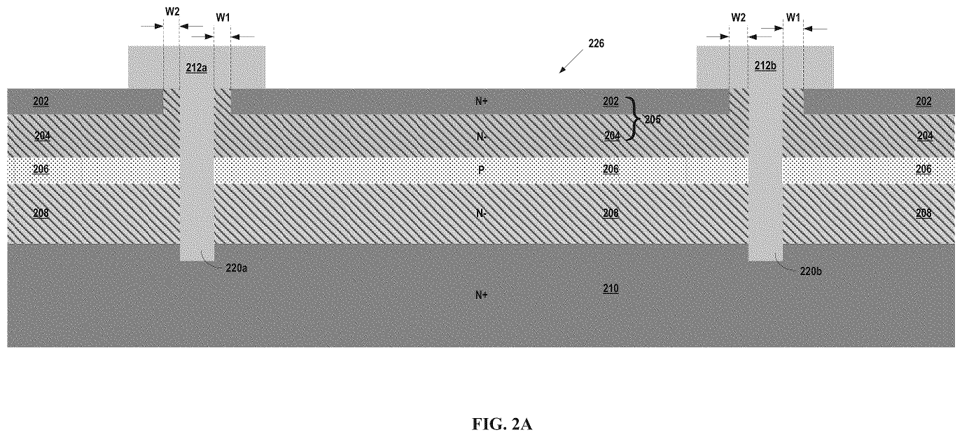

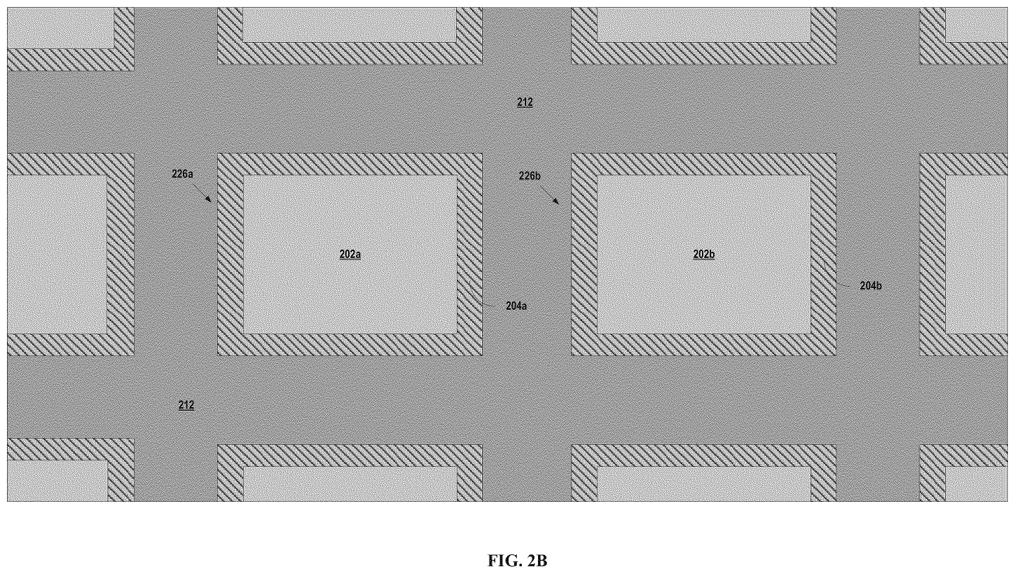

FIG. 2A is a partial sectional view of a phototransistor array included in an optical tweezers apparatus according to another implementation of the present invention, and FIG. 2B is a partial top view of the phototransistor array, that is, the phototransistor array may be used for forming the optical tweezers apparatus and a microfluidic device including the optical tweezers apparatus. As shown in the figures, the phototransistor array includes phototransistors 226 arranged in an array, and each phototransistor 226 is physically isolated from each other by an insulating layer 212 and an insulating barrier 220. The phototransistor 226 has a similar structure to the phototransistor 126, except that an emitter region 205 is different from the emitter region 105 of the phototransistor 126. In this embodiment, the emitter region 205 includes a first doped region 202 and a second doped region 204. The first doped region 202 and the second doped region 204 have a same doping type, and the first doped region 202 has a doping concentration greater than that of the second doped region 204. For example, when both the first doped region 202 and the second doped region 204 include an N-type dopant, the first doped region 202 is a heavily doped region N+, and the second doped region 204 is a lightly doped region N−.

The second doped region 204 laterally extends to adjacent insulating barriers 220a and 220b, and extends upward to the insulating layers 212a and 212b from a position adjacent to the insulating barrier 220 and surrounds the first doped region 202. The first doped region 202 laterally extends and abuts against an upward extension part of the second doped region 204. Therefore, the first doped region 202 is not in contact with the insulating barriers 220a and 220b. Similarly, in this embodiment, a thickness of the emitter region 205 (or a thickness of the second doped region 204) is substantially the same as a thickness of a collector region 208. For a relationship between a thickness of the first doped region 202 and a thickness of the second doped region 204, refer to descriptions of the thickness relationship between the first doped region 102 and the second doped region 104. Details are not described herein again. For a relationship between the thickness of the emitter region 205 and the thickness of the collector region 208, refer to descriptions of a relationship between the thickness H1+H2 of the emitter region 105 and the thickness H4 of the collector region 108. Details are not described herein again. For a relationship between the thickness of the second doped region 204 and the thickness of the collector region 208, refer to descriptions of a relationship between the thickness H2 of the second doped region 104 and the thickness H4 of the collector region 108. Details are not described herein again. Doping concentrations of the first doped region 202, the second doped region 204, and the collector region 208 and a relationship thereof are similar to those of the first doped region 102, the second doped region 104, and the collector region 108. Details are not described herein again.

A conductivity of the emitter region 205 is substantially equal to that of the collector region 208. Similarly, the thickness and the doping concentration of the emitter region 205 (including the first doped region 202 and/or the second doped region 204) and the thickness and the doping concentration of the collector region 208 may be adjusted as described above, to cooperatively increase or reduce the conductivities of the emitter region 205 and the collector region 208.

In this embodiment, the thickness of the first doped region 202 is about 150 nm, the thickness of the second doped region 204 is about 1000 nm, the thickness of the base region 206 is about 5000 nm, and the thickness of the collector region 208 is about 2000 nm. In this embodiment, the doping concentration of the first doped region 202 is about 2×10¹⁷ cm⁻³, the doping concentration of the second doped region 204 is about 1×10¹⁷ cm⁻³, the doping concentration of the base region 206 is about 1×10¹⁶ cm⁻³, and the doping concentration of the collector region 208 is about 2×10¹⁵ cm⁻³.

The second doped region 204 extends upward to form a lateral width W1 on a side of the insulating layer 212a and a lateral width W2 on a side of the insulating layer 212b. The insulating layers 212a and 212b completely cover the lateral widths W1 and W2, and cover at least a part of the first doped region 202. In this embodiment, the lateral widths W1 and W2 are substantially the same. The lateral widths W1 and W2 each may be, for example, 100 nm to about 2000 nm, 100 nm to about 1500 nm, 100 nm to about 1000 nm, 100 nm to about 800 nm, 100 nm to about 500 nm, 100 nm to about 300 nm, 100 nm to about 200 nm, 100 nm to about 150 nm, 300 nm to about 2000 nm, 300 nm to about 1500 nm, 300 nm to about 1000 nm, 300 nm to about 800 nm, 300 nm to about 500 nm, 500 nm to about 2000 nm, 500 nm to about 1500 nm, 500 nm to about 1000 nm, 500 nm to about 800 nm, 1000 nm to about 2000 nm, 1000 nm to about 1500 nm, or 1500 nm to about 2000 nm. In this embodiment, both the lateral width W1 and the lateral width W2 are 500 nm.

Volt-ampere characteristic curves of the phototransistor 226 provided in this embodiment are basically the same as the volt-ampere characteristic curves of the phototransistor 126 provided in the embodiment shown in FIG. 1A. For brevity, the volt-ampere characteristic curves of the phototransistor 226 are not repeated.

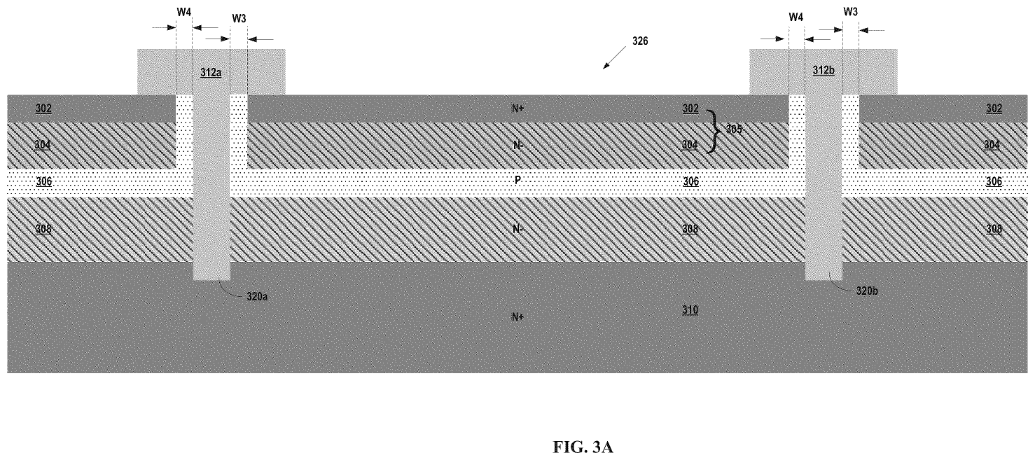

FIG. 3A is a partial sectional view of a phototransistor array included in an optical tweezers apparatus according to still another implementation of the present invention, and FIG. 3B is a partial top view of the phototransistor array, that is, the phototransistor may be used for forming the optical tweezers apparatus and a microfluidic device including the optical tweezers apparatus. As shown in the figures, the phototransistor array includes phototransistors 326 arranged in an array, and each phototransistor 326 is physically isolated from each other by an insulating layer 312 and an insulating barrier 320. The phototransistor 326 includes an emitter region 305, a base region 306, a collector region 308, and a substrate 310. The emitter region 305 includes a first doped region 302 and a second doped region 304. The first doped region 302 and the second doped region 304 have a same doping type, and the first doped region 302 has a doping concentration greater than that of the second doped region 304. For example, when both the first doped region 302 and the second doped region 304 include an N-type dopant, the first doped region 302 is a heavily doped region N+, and the second doped region 304 is a lightly doped region N−.

The base region 306 laterally extends to adjacent insulating barriers 320a and 320b, and extends upward to the insulating layers 312a and 312b from a position adjacent to the insulating barrier 320 and surrounds the first doped region 302 and the second doped region 304. The first doped region 302 and the second doped region 304 laterally and parallelly extend and abut against an upward extension part of the base region 306. Therefore, neither the first doped region 302 nor the second doped region 304 is in contact with the insulating barriers 320a and 320b. The base region 306 is simultaneously in contact with the first doped region 302 and the second doped region 304.

Similarly, in this embodiment, a thickness of the emitter region 305 is substantially the same as a thickness of the collector region 308, or a thickness of the second doped region 304 is substantially the same as a thickness of the collector region 308. For a relationship between a thickness of the first doped region 302 and a thickness of the second doped region 304, refer to descriptions of the thickness relationship between the first doped region 102 and the second doped region 104. Details are not described herein again. For a relationship between the thickness of the emitter region 305 and the thickness of the collector region 308, refer to descriptions of a relationship between the thickness H1+H2 of the emitter region 105 and the thickness H4 of the collector region 108. Details are not described herein again. For a relationship between the thickness of the second doped region 304 and the thickness of the collector region 308, refer to descriptions of a relationship between the thickness H2 of the second doped region 104 and the thickness H4 of the collector region 108. Details are not described herein again. Doping concentrations of the first doped region 302, the second doped region 304, and the collector region 308 and a relationship thereof are similar to those of the first doped region 102, the second doped region 104, and the collector region 108. Details are not described herein again.

A conductivity of the emitter region 305 is substantially equal to that of the collector region 308. Similarly, the thickness and the doping concentration of the emitter region 305 (including the first doped region 302 and/or the second doped region 304) and the thickness and the doping concentration of the collector region 308 may be adjusted as described above, to cooperatively increase or reduce the conductivities of the emitter region 305 and the collector region 308.

In this embodiment, the thickness of the first doped region 302 is about 500 nm, the thickness of the second doped region 304 is about 1500 nm, the thickness of the base region 306 is about 1000 nm, and the thickness of the collector region 308 is about 2000 nm. In this embodiment, the doping concentration of the first doped region 302 is about 1×10¹⁸ cm⁻³, the doping concentration of the second doped region 304 is about 1×10¹⁷ cm⁻³, the doping concentration of the base region 306 is about 1×10¹⁶ cm⁻³, and the doping concentration of the collector region 308 is about 2×10¹⁵ cm⁻³.

The base region 306 extends upward and surrounds the first doped region 302 and the second doped region 304, to form a lateral width W3 on a side of the insulating layer 312a and a lateral width W4 on a side of the insulating layer 312b. The insulating layers 312a and 312b completely cover the lateral widths W3 and W4, and cover at least a part of the first doped region 302. In this embodiment, the lateral widths W3 and W4 are substantially the same. The lateral widths W3 and W4 each may be, for example, 100 nm to about 2000 nm, 100 nm to about 1500 nm, 100 nm to about 1000 nm, 100 nm to about 800 nm, 100 nm to about 500 nm, 100 nm to about 300 nm, 100 nm to about 200 nm, 100 nm to about 150 nm, 300 nm to about 2000 nm, 300 nm to about 1500 nm, 300 nm to about 1000 nm, 300 nm to about 800 nm, 300 nm to about 500 nm, 500 nm to about 2000 nm, 500 nm to about 1500 nm, 500 nm to about 1000 nm, 500 nm to about 800 nm, 1000 nm to about 2000 nm, 1000 nm to about 1500 nm, or 1500 nm to about 2000 nm. In this embodiment, both the lateral width W3 and the lateral width W4 are 500 nm. In another embodiment, the lateral width W3 and the lateral width W4 may have different sizes.

In this embodiment, surrounding the emitter region 305 by the base region 306 may help resolve a leakage problem of the phototransistor that may be caused by a manufacturing process defect, that is, there is no difference between volt-ampere characteristic curves of the phototransistor in an activated (for example, light irradiation) state and a non-activated (for example, without light) state. For example, a possible process defect is that in a process of ion implantation of a dopant (for example, a P-type dopant) to form the base region 306, the P-type dopant (for example, boron) is excessively diffused into the insulating barrier 320 at a position adjacent to the insulating barrier 320 (for example, made of a SiO₂ material), resulting in a non-uniform doping concentration of the base region 306 at the position adjacent to the insulating barrier 320, or even no doping. This in turn results in formation of a carrier channel from the emitter region to a non-uniform doped/non-doped region to the collector region, while avoiding the base region 306, resulting in the foregoing leakage problem after a voltage is applied.

In this embodiment, the base region 306 surrounds the emitter region 305, so that there is a larger contact area between the base region 306 and the insulating barrier 320, to implement more fully ion implantation, thereby reducing a possibility of the foregoing non-uniform doping, and reducing or eliminating the foregoing leakage risk. In addition, the base region 306 surrounds the emitter region 305, so that the base region 306 has an increased light irradiation area (a part surrounding the emitter region 305), thereby generating a stronger current and a stronger DEP force, and helping manipulate microobjects in a microfluidic channel.

FIG. 6C shows volt-ampere characteristic curves of the phototransistor according to this embodiment, where the alternating current AC is applied between the two electrodes of the optical tweezers apparatus. When the patterned light is irradiated on the phototransistor, the phototransistor is turned on, and a volt-ampere characteristic curve of the phototransistor is shown as a curve A in the figure. In this case, a current intensity at a positive voltage is equivalent to a current intensity at a corresponding negative voltage. When there is no light irradiation, the phototransistor is in a cut-off state, but a leakage current still passes through the phototransistor, and a volt-ampere characteristic curve of the leakage current is shown as a curve B in the figure. A current intensity of the leakage current in a positive voltage cycle is almost the same as that at an equal voltage in a negative voltage cycle. For example, when +10 μV, an intensity of the leakage current is about +1.5 μA, which corresponds to an intercept S5 obtained from vertical coordinates. When −10 μV, an intensity of the leakage current is about −1.5 μA, which corresponds to an intercept S6 obtained from vertical coordinates. Compared with the conventional technology in FIG. 6A, an intensity of a positive leakage current is significantly reduced, the intensity of the positive leakage current is basically the same as that of a negative leakage current, thus reducing or eliminating a possibility of an electrochemical reaction.

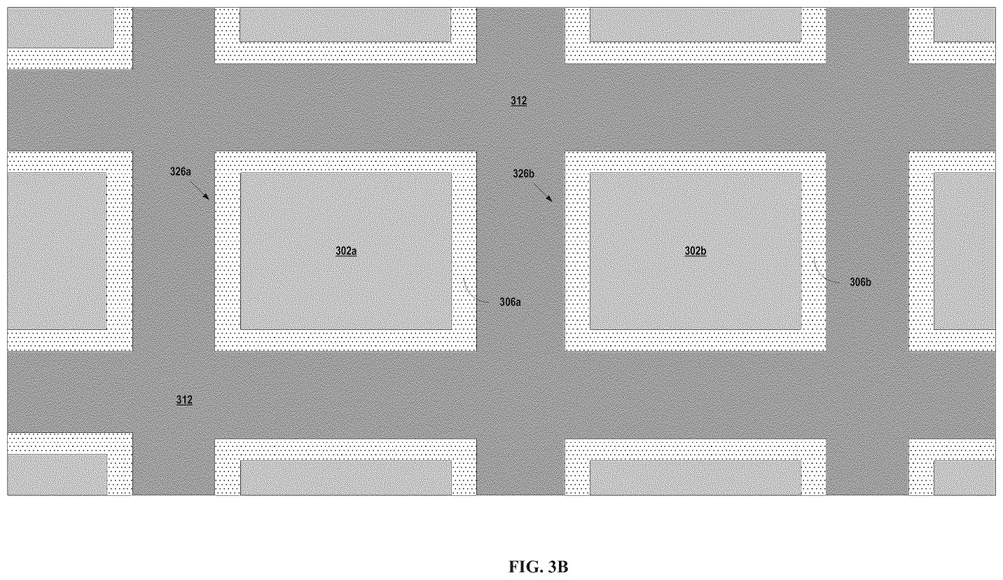

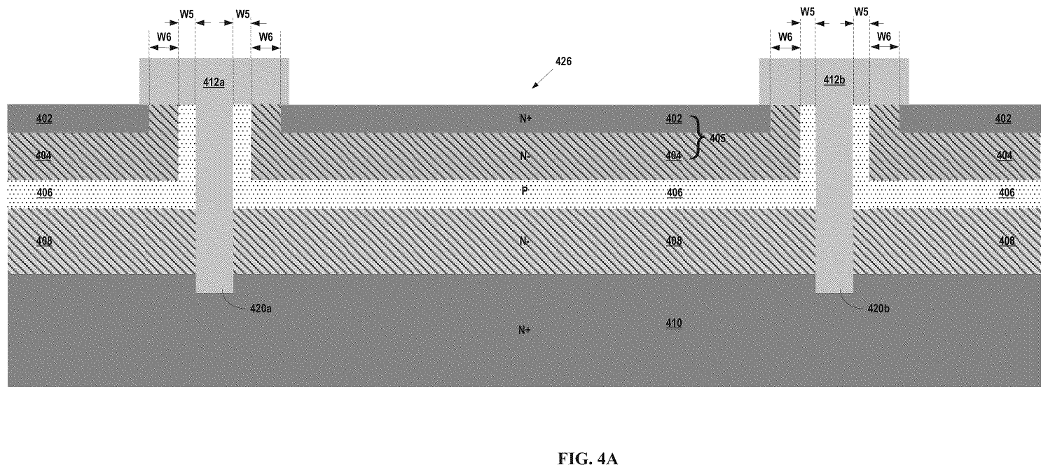

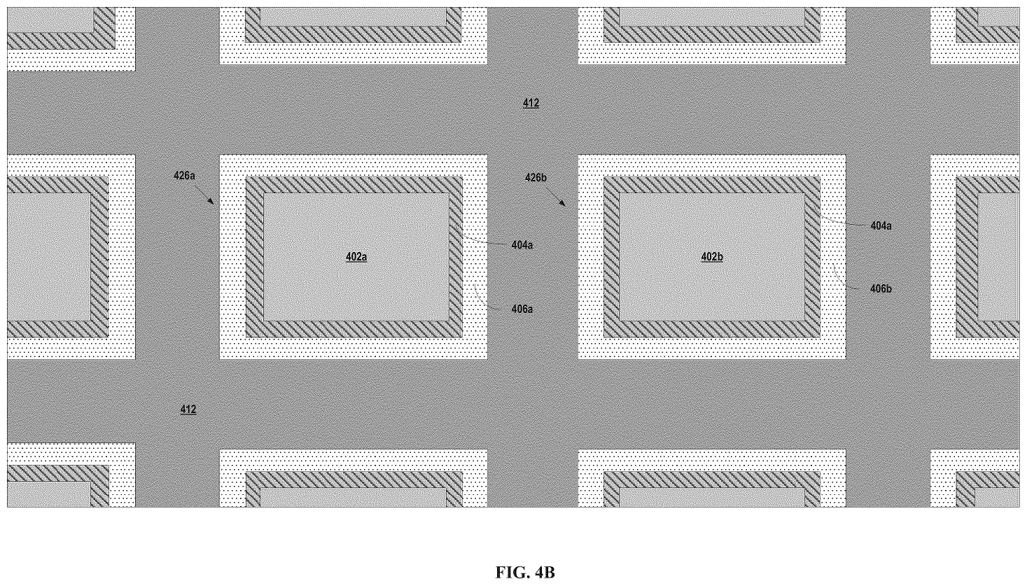

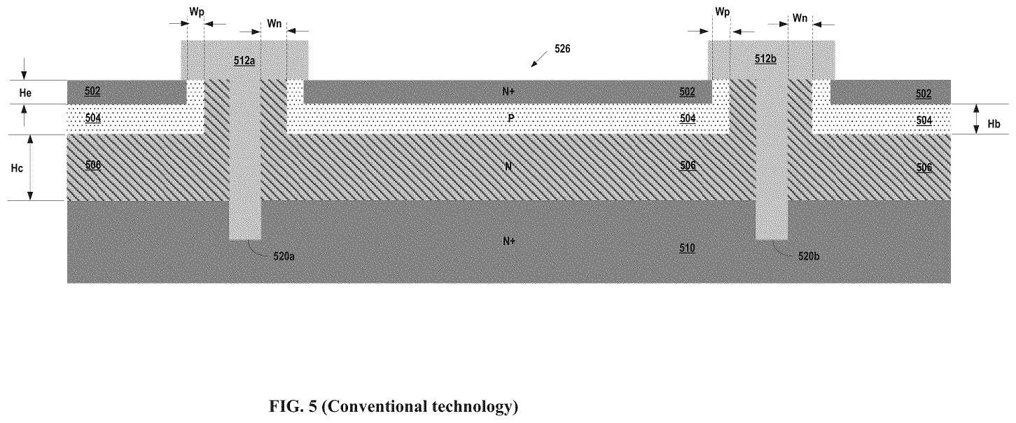

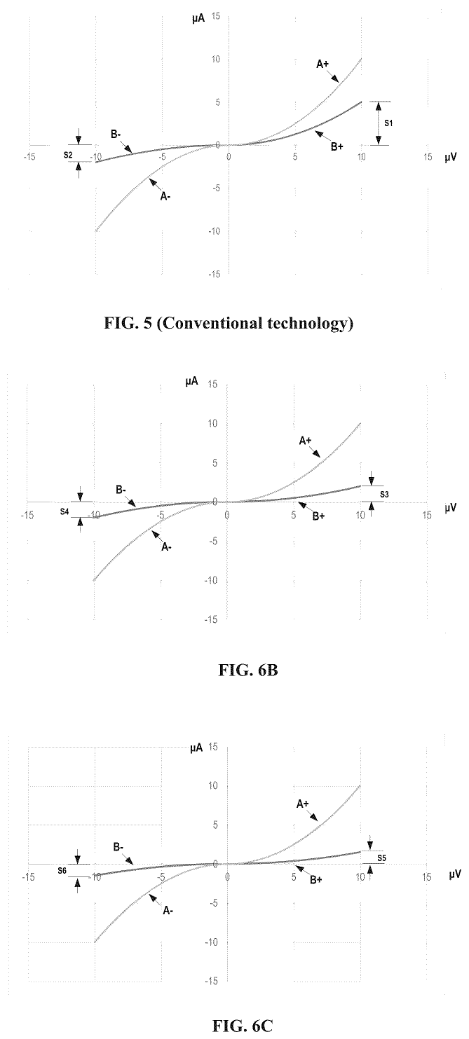

FIG. 4A is a partial sectional view of a phototransistor array included in an optical tweezers apparatus according to yet another implementation of the present invention, and FIG. 4B is a partial top view of the phototransistor array, that is, the phototransistor may be used for forming the optical tweezers apparatus and a microfluidic device including the optical tweezers apparatus. As shown in the figures, the phototransistor array includes phototransistors 426 arranged in an array, and each phototransistor 426 is physically isolated from each other by an insulating layer 412 and an insulating barrier 420. The phototransistor 426 includes an emitter region 405, a base region 406, a collector region 408, and a substrate 410. The emitter region 405 includes a first doped region 402 and a second doped region 404. The first doped region 402 and the second doped region 404 have a same doping type, and the first doped region 402 has a doping concentration greater than that of the second doped region 404. For example, when both the first doped region 402 and the second doped region 404 include an N-type dopant, the first doped region 402 is a heavily doped region N+, and the second doped region 404 is a lightly doped region N−.

The base region 406 laterally extends to adjacent insulating barriers 420a and 420b, and extends upward to insulating layers 412a and 412b from a position adjacent to the insulating barrier 420 and surrounds the emitter region 405. The second doped region 404 laterally extends to the base region 406, and extends upward to the insulating layers 412a and 412b from a position adjacent to the base region 406 and surrounds the first doped region 402. The first doped region 402 laterally extends and abuts against an upward extension part of the second doped region 404. Therefore, neither the first doped region 402 nor the second doped region 404 is in contact with the insulating barriers 220a and 220b.

The base region 406 surrounds the second doped region 404 and the upward extension part of the second doped region 404, and therefore also surrounds the first doped region 402. The second doped region 404 extends laterally and parallel to the first doped region 402 and the base region 406, and abuts against an upward extension part of the base region 406. The base region 406 contacts the second doped region 404 but does not contact the first doped region 402.

The base region 406 extends upward and surrounds the first doped region 402 and the second doped region 404 to form a lateral width W5 adjacent to the insulating barriers 420a and 420b, and the second doped region 404 extends upward and surrounds the first doped region 402 to form a lateral width W6 away from the insulating barriers 420a and the 420b. The insulating layers 412a and 412b completely cover the lateral widths W5 and W6, and cover at least a part of the first doped region 402.

The lateral widths W5 and W6 each may be, for example, 100 nm to about 2000 nm, 100 nm to about 1500 nm, 100 nm to about 1000 nm, 100 nm to about 800 nm, 100 nm to about 500 nm, 100 nm to about 300 nm, 100 nm to about 200 nm, 100 nm to about 150 nm, 300 nm to about 2000 nm, 300 nm to about 1500 nm, 300 nm to about 1000 nm, 300 nm to about 800 nm, 300 nm to about 500 nm, 500 nm to about 2000 nm, 500 nm to about 1500 nm, 500 nm to about 1000 nm, 500 nm to about 800 nm, 1000 nm to about 2000 nm, 1000 nm to about 1500 nm, or 1500 nm to about 2000 nm. In this embodiment, both the lateral width W5 and the lateral width W4 are 500 nm. In another embodiment, the lateral width W5 and the lateral width W6 may have different sizes.

Similarly, in this embodiment, a thickness of the emitter region 405 is substantially the same as a thickness of the collector region 408, or a thickness of the second doped region 404 is substantially the same as a thickness of the collector region 408. For a relationship between a thickness of the first doped region 402 and a thickness of the second doped region 404, refer to descriptions of the thickness relationship between the first doped region 102 and the second doped region 104. Details are not described herein again. For a relationship between the thickness of the emitter region 405 and the thickness of the collector region 408, refer to descriptions of a relationship between the thickness H1+H2 of the emitter region 105 and the thickness H4 of the collector region 108. Details are not described herein again. For a relationship between the thickness of the second doped region 404 and the thickness of the collector region 408, refer to descriptions of a relationship between the thickness H2 of the second doped region 104 and the thickness H4 of the collector region 108. Details are not described herein again. Doping concentrations of the first doped region 402, the second doped region 404, and the collector region 408 and a relationship thereof are similar to those of the first doped region 102, the second doped region 104, and the collector region 108. Details are not described herein again.

A conductivity of the emitter region 405 is substantially equal to that of the collector region 408. Similarly, the thickness and the doping concentration of the emitter region 405 (including the first doped region 402 and/or the second doped region 404) and the thickness and the doping concentration of the collector region 408 may be adjusted as described above, to cooperatively increase or reduce the conductivities of the emitter region 405 and the collector region 408.

In this embodiment, the thickness of the first doped region 402 is about 500 nm, the thickness of the second doped region 404 is about 1500 nm, the thickness of the base region 406 is about 500 nm, and the thickness of the collector region 408 is about 2000 nm. In this embodiment, the doping concentration of the first doped region 302 is about 1×10¹⁸ cm⁻³, the doping concentration of the second doped region 404 is about 1×10¹⁷ cm⁻³, the doping concentration of the base region 406 is about 1×10¹⁶ cm⁻³, and the doping concentration of the collector region 408 is about 2×10¹⁵ cm⁻³.

Volt-ampere characteristic curves of the phototransistor 426 provided in this embodiment are basically the same as the volt-ampere characteristic curves of the phototransistor 326 provided in the embodiment shown in FIG. 3A. For brevity, the volt-ampere characteristic curves of the phototransistor 426 are not repeated.

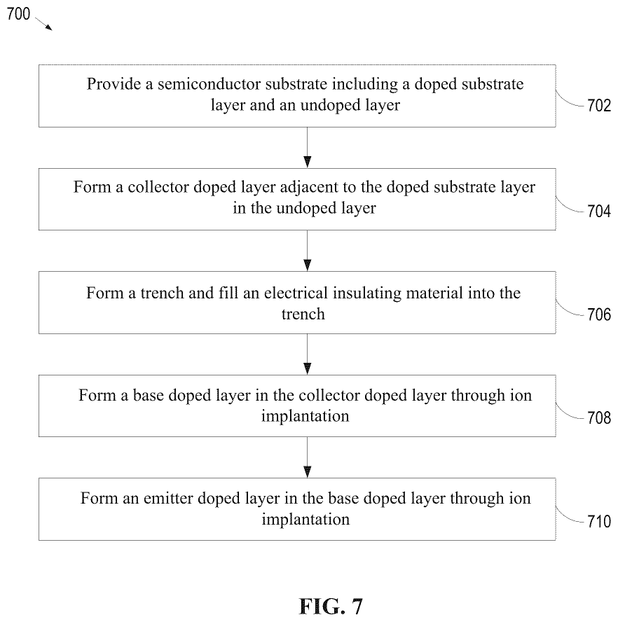

The phototransistor, the optical tweezers apparatus, and the microfluidic device provided in the present invention may be prepared by using a conventional technology in the art. Based on a level of an existing semiconductor manufacturing process and with reference to the diagrams and descriptions of the specification, a person skilled in the art can manufacture the phototransistor of the present invention without special descriptions. As an example only, FIG. 7 schematically shows a method 700 for manufacturing a phototransistor according to the present invention.

The method 700 includes step 702, which provides a semiconductor substrate (for example, silicon) that includes a doped substrate layer and an undoped layer located on the doped substrate layer. The doped substrate layer is used for forming a substrate in the embodiments of the present invention, and the undoped layer is used for forming a collector region, a base region, and an emitter region in the embodiments of the present invention.

In step 704, a collector doped layer adjacent to the doped substrate layer is formed in the undoped layer, and the collector doped layer forms a collector region in the embodiments of the present invention, where the collector doped layer and the doped substrate layer may have a same doping type (for example, both are N-type doping), but may have different doping concentrations. For example, the collector doped layer is a lightly doped layer, and the doped substrate layer is a heavily doped layer. A semiconductor material obtained after step 704 includes the doped substrate layer and the collector doped layer.

In step 706, a trench is formed in the obtained semiconductor material, and an electrical insulating material is filled in the trench. The trench penetrates the collector doped layer and extends into the doped substrate layer, to form an insulating barrier in the embodiments of the present invention.

Further, in step 708, a base doped layer is formed in the collector doped layer through ion implantation, and the base doped layer has a doping type (for example, P-type doping) different from that of the collector doped layer and the doped substrate layer. By controlling parameters such as a time, a speed, and an implantation amount of ion implantation, thicknesses of the formed base doped layer and collector doped layer may be controlled, to meet a requirement of the present invention for the thicknesses of the base doped layer and the collector doped layer.

In step 710, an emitter doped layer is formed in the base doped layer through ion implantation, and the emitter doped layer has a different doping type (for example, N-type doping) from the base doped layer. A first doped layer and a second doped layer with different doping concentrations may be formed for the emitter doped layer by using an independent ion implantation step, for example, the doping concentration of the first doped layer is greater than the doping concentration of the second doped layer, to form a first doped region and a second doped region of an emitter region in the embodiments of the present invention. Similarly, by controlling parameters such as a time, a speed, and an implantation amount of ion implantation, thicknesses of the formed first doped layer, second doped layer, and base doped layer may be controlled, to meet a requirement of the present invention for the thicknesses of the layers.

It should be noted that although the doping types and the doping levels are represented in the figure, a person skilled in the art knows that an illustrated NPN-type phototransistor may be replaced by a PNP-type phototransistor structure without affecting implementation of the objectives of the embodiments of the present invention.

The foregoing descriptions are representative examples of the implementations of the present invention, and are provided for illustrative purposes only. One or more technical features expected to be used in an implementation in the present invention may be added to another implementation without departing from the purpose of the implementation, to form an improved or alternative implementation. Similarly, one or more technical features used in an implementation may be omitted or replaced without departing from the purpose of the implementation, to form an alternative or simplified implementation. In addition, one or more technical features used in an implementation may be combined with one or more technical features in another implementation without departing from the purpose of the implementation, to form an improved or alternative implementation. The present invention is intended to include all of the foregoing improved, alternative, and simplified technical solutions.

What is claimed is:

1. An optical tweezers apparatus, comprising:
a first electrode;
a second electrode;
a phototransistor array located between the first electrode and the second electrode, wherein the phototransistor array comprises phototransistors distributed in an array, each phototransistor is physically isolated from each other by an insulating layer and an insulating barrier, each phototransistor comprises a collector region, a base region, and an emitter region on a substrate, the collector region and the emitter region have a first doping type, and the base region has a second doping type; and
a microfluidic channel formed between the first electrode and the phototransistor array, wherein
when an alternating current is applied between the first electrode and the second electrode, the phototransistor in a non-activated state has a positive leakage current and a negative leakage current respectively in a positive half cycle and a negative half cycle of the alternating current; and
the collector region and the emitter region have substantially equal conductivities or resistivities, so that the phototransistor has substantially symmetrical positive leakage current and negative leakage current.

2. The optical tweezers apparatus according to claim 1, wherein the emitter region comprises a first doped region and a second doped region, and a doping concentration of the first doped region is greater than that of the second doped region.

3. The optical tweezers apparatus according to claim 2, wherein the first doped region has a first thickness, the second doped region has a second thickness, and a ratio of the first thickness to the second thickness is about 1:1 to about 1:30.

4. The optical tweezers apparatus according to claim 3, wherein the collector region has a third thickness, the emitter region has a fourth thickness, and a ratio of the third thickness to the fourth thickness is about 1:5 to about 5:1.

5. The optical tweezers apparatus according to claim 3, wherein the collector region has a third thickness, and a ratio of the third thickness to the second thickness is about 1:5 to about 5:1.

6. The optical tweezers apparatus according to claim 2, wherein the base region, the first doped region, and the second doped region separately laterally extend to the insulating barrier.

7. The optical tweezers apparatus according to claim 2, wherein the first doped region and the second doped region laterally extend, and the second doped region at least partially surrounds the first doped region.

8. The optical tweezers apparatus according to claim 7, wherein the second doped region surrounds the first doped region by a first lateral width of about 100 nm to about 2000 nm.

9. The optical tweezers apparatus according to claim 2, wherein the base region, the first doped region, and the second doped region laterally extend, and the base region at least partially surrounds the first doped region and the second doped region.

10. The optical tweezers apparatus according to claim 9, wherein the base region surrounds the first doped region and the second doped region by a second lateral width of about 100 nm to about 2000 nm.

11. The optical tweezers apparatus according to claim 2, wherein the base region, the first doped region, and the second doped region laterally extend, the base region at least partially surrounds the first doped region and the second doped region, and the second doped region at least partially surrounds the first doped region.

12. The optical tweezers apparatus according to claim 11, wherein the base region surrounds the first doped region and the second doped region by a second lateral width of about 100 nm to about 2000 nm, and the second doped region surrounds the first doped region by a first lateral width of about 100 nm to about 2000 nm.

13. The optical tweezers apparatus according to claim 2, wherein the collector region and the second doped region have substantially equal doping concentrations.

14. The optical tweezers apparatus according to claim 13, wherein the doping concentrations of the collector region and the second doped region are about 10¹⁵ cm⁻³ to about 10¹⁸ cm⁻³.

15. The optical tweezers apparatus according to claim 2, wherein a doping concentration of the first doped region is about 10¹⁸ cm⁻³ to about 10²¹ cm⁻³.

16. The optical tweezers apparatus according to claim 2, wherein the substrate and the first doped region have a same doping concentration.

17. The optical tweezers apparatus according to claim 1, wherein the first doping type is N-type doping, and the second doping type is P-type doping.

18. The optical tweezers apparatus according to claim 1, wherein a liquid sample is filled in the microfluidic channel, and a conductivity of the liquid sample is about 1 mS/cm to about 10 mS/cm.

19. The optical tweezers apparatus according to claim 1, wherein the emitter region comprises a plurality of emitter sub-regions.

20. A microfluidic device, comprising a control system, an optical pattern generation system, an image collection system, and an optical tweezers apparatus, wherein the optical tweezers apparatus is the optical tweezers apparatus according to claim 1.
